(19) United States
(12) Patent Application Publication
(10) Pub. No.: US 2026/0058657 A1
(43) Pub. Date: Feb. 26, 2026

(54) SiC-BASED POWER MODULE UTILIZING HIGH-TEMPERATURE GATE DRIVERS WITH OPTICAL FIBER-BASED ISOLATORS

(71) Applicant: BOARD OF TRUSTEES OF THE UNIVERSITY OF ARKANSAS, Little Rock, AR (US)

(72) Inventors: Zhong Chen, Fayetteville, AR (US); H. Alan Mantooth, Fayetteville, AR (US); Sudharsan Chinnaiyan, Fayetteville, AR (US); Pengyu Lai, Fayetteville, AR (US)

(73) Assignee: BOARD OF TRUSTEES OF THE UNIVERSITY OF ARKANSAS, Little Rock, AR (US)

(21) Appl. No.: 19/310,281

(22) Filed: Aug. 26, 2025

Related U.S. Application Data
(60) Provisional application No. 63/687,185, filed on Aug. 26, 2024.

(51) Int. Cl. H03K 17/785

(52) U.S. Cl. CPC H03K 17/785

(57) ABSTRACT

A power module that utilizes high-temperature gate drivers with optical fiber-based isolators. The power module includes a gate driver, which includes one or more optical fiber-based isolators configured to provide electrical isolation between low-voltage circuitry and power devices of the power module. Furthermore, the gate driver includes an amplifier configured to enhance a control signal. Additionally, the gate driver includes a gate driver integrated circuit configured to provide voltage and current to drive the power devices of the power module based on the control signal. Furthermore, the gate driver is fabricated on a substrate, such as a low-temperature co-fired ceramic substrate. As a result, the power module with the optical fiber-based isolator allows for a wide range of operation temperatures and fast switching frequency.

### STATEMENT REGARDING FEDERALLY SPONSORED RESEARCH

This invention was made with government support under EEC-1449548 awarded by the National Science Foundation. The government has certain rights in the invention.

### TECHNICAL FIELD

The present disclosure relates generally to SiC-based power modules, and more particularly to an SiC-based power module that utilizes high-temperature gate drivers with optical fiber-based isolators.

### BACKGROUND

Silicon carbide (SiC) is one of the most commonly used materials in power applications due to its wide energy bandgap, high electric field strength, and high thermal conductivity. This significantly increases the power rating, operating voltage, and power density of power modules. Despite the superior temperature tolerance of SiC power devices, the working temperature of power modules is still limited by packaging materials and other passive components. Moreover, to reduce the parasitic elements and improve the switching behaviors, gate driver circuitry is designed to be tightly integrated with the power devices. As a result, the operating temperature of the gate driver is required to be similar to that of the power devices.

As a result, a high-temperature SiC-based power module with integrated low-temperature co-fired ceramic (LTCC) based gate drivers has been developed. Compared to printed circuit board (PCB)-based circuitry, LTCC-based circuitry has higher temperature tolerance, and its coefficient of thermal expansion (CTE) is closer to the substrate of power modules. This makes LTCC-based circuitry promising to be integrated into SiC power modules, especially for high-temperature applications.

However, the propagation delay of the fabricated LTCC-based gate driver is higher than 2 μs, which significantly limits the switching frequency of the SiC power module. This is due to the high junction capacitance and low output current of the optocoupler-based isolator for the LTCC-based gate driver.

Consequently, a high-temperature SiC-based power module with integrated low-temperature co-fired ceramic (LTCC) based gate drivers needs to be developed that addresses the high junction capacitance and low output current of the optocoupler-based isolator for the LTCC-based gate driver.

### SUMMARY

In one embodiment of the present disclosure, a power module comprises a gate driver, where the gate driver comprises one or more optical fiber-based isolators configured to provide electrical isolation between low-voltage circuitry and power devices of the power module. The gate driver further comprises an amplifier configured to enhance a control signal. The gate driver additionally comprises a gate driver integrated circuit configured to provide voltage and current to drive the power devices of the power module based on the control signal.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1A illustrates a power module in accordance with an embodiment of the present disclosure;

FIG. 1B illustrates the internal architecture of the power module in accordance with an embodiment of the present disclosure;

FIG. 1C illustrates an embodiment of the gate driver in accordance with an embodiment of the present disclosure;

FIG. 1D illustrates the optical fiber-based isolator in accordance with an embodiment of the present disclosure;

FIG. 2 illustrates the schematic of a high-temperature SiC power module with an integrated gate driver in accordance with an embodiment of the present disclosure;

FIG. 3A illustrates a three-dimensional model of the gate driver in accordance with an embodiment of the present disclosure;

FIG. 3B illustrates an example of a fabricated sample of the LTCC-based gate driver in accordance with an embodiment of the present disclosure;

FIG. 4 illustrates a high-temperature SiC power module with LTCC-based optical fiber-based isolated gate drivers in accordance with an embodiment of the present disclosure;

FIG. 5 is a flowchart of a method for fabricating the high-temperature SiC power module of FIG. 4 in accordance with an embodiment of the present disclosure;

FIGS. 6A-6H depict the cross-sectional views for fabricating the high-temperature SiC power module of FIG. 4 using the steps described in FIG. 5 in accordance with an embodiment of the present invention; and

FIGS. 7A-7C illustrate the results from performing the double pulse tests (DPTs) on the power module from 25° C. to 200° C. in accordance with an embodiment of the present disclosure.

### DETAILED DESCRIPTION

As stated above, silicon carbide (SiC) is one of the most commonly used materials in power applications due to its wide energy bandgap, high electric field strength, and high thermal conductivity. This significantly increases the power rating, operating voltage, and power density of power modules. Despite the superior temperature tolerance of SiC power devices, the working temperature of power modules is still limited by packaging materials and other passive components. Moreover, to reduce the parasitic elements and improve the switching behaviors, gate driver circuitry is designed to be tightly integrated with the power devices. As a result, the operating temperature of the gate driver is required to be similar to that of the power devices.

As a result, a high-temperature SiC-based power module with integrated low-temperature co-fired ceramic (LTCC) based gate drivers has been developed. Compared to printed circuit board (PCB)-based circuitry, LTCC-based circuitry has higher temperature tolerance, and its coefficient of thermal expansion (CTE) is closer to the substrate of power modules. This makes LTCC-based circuitry promising to be integrated into SiC power modules, especially for high-temperature applications.

However, the propagation delay of the fabricated LTCC-based gate driver is higher than 2 μs, which significantly limits the switching frequency of the SiC power module. This is due to the high junction capacitance and low output current of the optocoupler-based isolator for the LTCC-based gate driver.

Consequently, a high-temperature SiC-based power module with integrated low-temperature co-fired ceramic (LTCC) based gate drivers needs to be developed that addresses the high junction capacitance and low output current of the optocoupler-based isolator for the LTCC-based gate driver.

The embodiments of the present disclosure provide a novel SiC power module with optical fiber-based isolated low-temperature co-fired ceramic (LTCC) drivers which allows for a wide range of operation temperatures and fast switching frequency.

In one embodiment, an optical fiber-based isolator is utilized to replace the optocoupler-based isolator used in prior power modules. The optical fiber-based isolator is immune from electromagnetic interference (EMI) thereby eliminating the need for the optical fiber-based isolator to be shielded from outside noise sources or to be subject to crosstalk or jitter from other nearby lines. Furthermore, since optical fibers can handle much higher frequencies over longer distances than cooper wires used by optocoupler-based isolators, the emitter of the optical fiber-based isolator can be integrated with the logic controllers, which allows it to operate at room temperature. Therefore, the degradation of the optical isolator at high temperatures can be significantly improved.

As previously discussed, in one embodiment, an optical-fiber-based isolator is utilized to replace the optocoupler-based isolator used in prior power modules to achieve a faster switching speed for the high-temperature power module. In one embodiment, the optical fiber-based isolator consists of three parts: an emitter, an optical fiber cable, and a detector. The emitter of the optical fiber-based isolator is integrated with logic control circuits of the power module that operate at room temperature. In one embodiment, the emitter is configured to convert an electrical signal into a corresponding optical or light signal. In one embodiment, the optical fiber cable is a high-temperature optical fiber cable that is utilized to transfer the optical or light signal produced by the emitter to the detector. In one embodiment, the detector, which may be a high-temperature detector, is integrated with the gate driver circuit and implemented to convert the optical or light signal produced by the emitter to an electrical signal. In one embodiment, in order to achieve high reliability at high-temperature conditions, LTCC material is used as the substrate of the gate driver circuitry. LTCC substrates have the capacity to withstand high operating temperatures (e.g., 400° C.) and have also been demonstrated to be easily integrated into power modules. Furthermore, in one embodiment, high-temperature packaging materials are utilized for the encapsulation of the power module, which allows the SiC power module to operate up to 200° C.

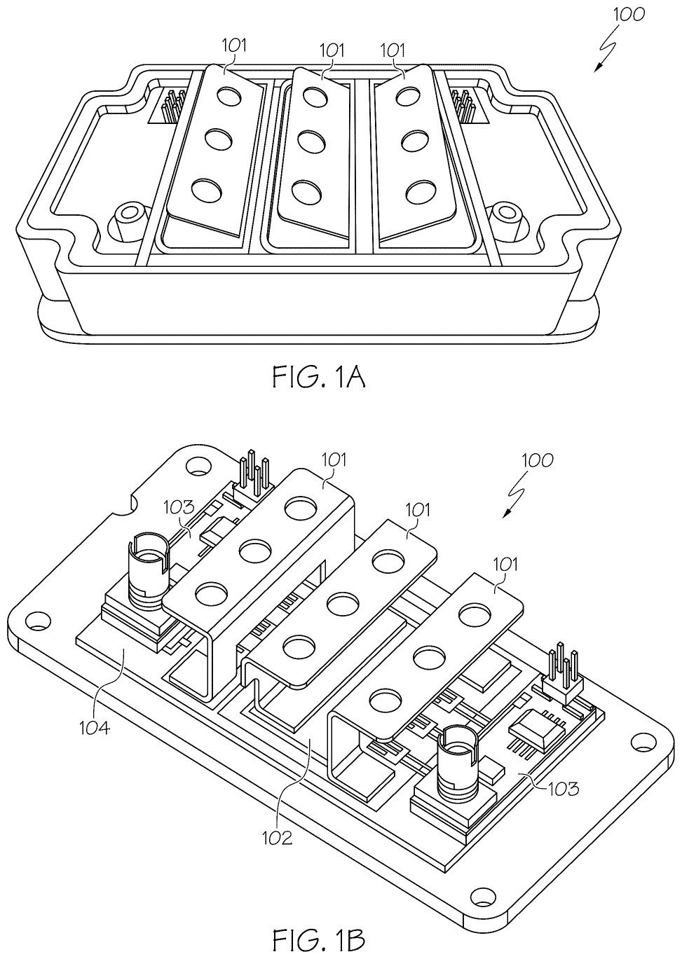

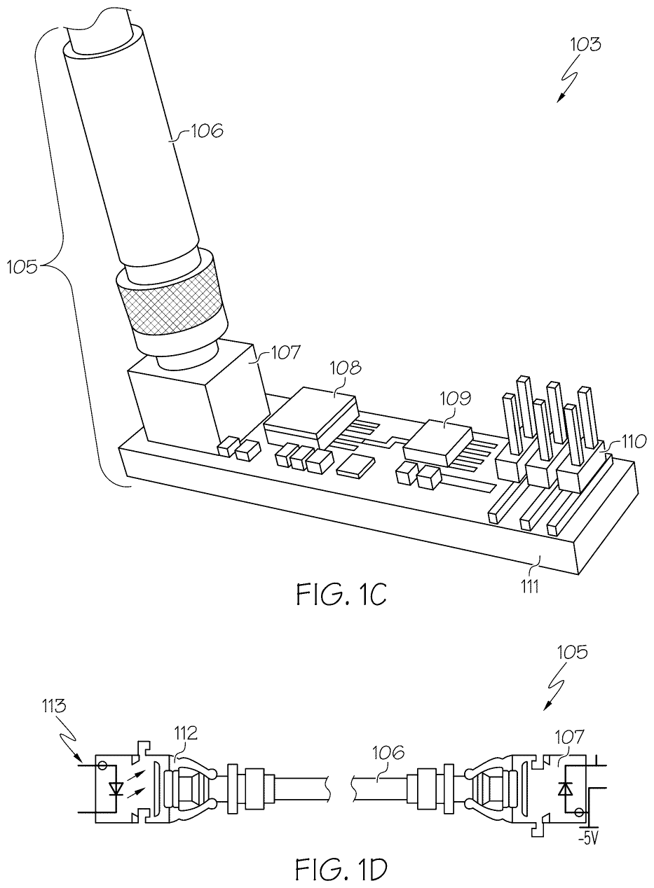

Referring now to the Figures in detail, FIG. 1A illustrates a power module 100 in accordance with an embodiment of the present disclosure.

As shown in FIG. 1A, power module 100 includes power terminals 101 configured to provide power supply connections to the power circuits boards 102 (see FIG. 1B) of power module 100.

FIG. 1B illustrates the internal architecture of power module 100 in accordance with an embodiment of the present disclosure.

As shown in FIG. 1B, power module 100 includes one or more gate drivers 103 fabricated on a substrate 104. Gate drivers 103, as used herein, refer to electronic circuits that control how well the power switches (e.g., insulated gate bipolar transistors (IGBTs), metal oxide semiconductor field-effect transistors (MOSFETs), etc.) of power module 100 work. That is, gate drivers 103 are configured to turn these power devices/power switches on and off. For example, gate drivers 103 may include a power amplifier that accepts a low-power input from a controller integrated circuit and produces a high current to drive the gate of a power device.

FIG. 1C illustrates an embodiment of gate driver 103 in accordance with an embodiment of the present disclosure

As shown in FIG. 1C, in one embodiment, gate driver 103 includes one or more optical fiber-based isolators 105 that each includes an optical fiber cable 106 in optical communication with a detector 107. In one embodiment, optical fiber-based isolator 105 is configured to protect low-voltage control circuitry (e.g., where gate driver integrated circuit 109 resides) and the high-voltage power components (e.g., power devices 110). In one embodiment, optical fiber-based isolator 105 is immune from electromagnetic interference. In one embodiment, gate driver 103 includes two optical fiber-based isolators 105.

In one embodiment, optical fiber cable 106 is configured to transfer an optical (light) signal from an emitter (shown in FIG. 1D) to detector 107. In one embodiment, detector 107 is configured to convert the optical signal received from optical fiber cable 106 to an electrical signal.

Furthermore, as illustrated in FIG. 1C, gate driver 103 includes an amplifier 108 configured to enhance a control signal, such as a voltage signal, received from detector 107 of optical fiber-based isolator 105.

Additionally, as illustrated in FIG. 1C, gate driver 103 includes a gate driver integrated circuit 109 configured to receive a control signal (e.g., voltage signal), such as the control signal from amplifier 108, and then provide the necessary voltage and current to drive power devices/power switches 110 (e.g., IGBTs, MOSFETs, etc.) of power module 100.

In one embodiment, gate driver 103 is fabricated on a substrate 111. In one embodiment, substrate 111 is a low-temperature co-fired ceramic (LTCC) substrate.

Referring now to FIG. 1D, FIG. 1D illustrates optical fiber-based isolator 105 in accordance with an embodiment of the present disclosure.

As shown in FIG. 1D, in one embodiment, optical fiber-based isolator 105 includes an emitter 112 configured to convert an input 113 (electrical signal) into a corresponding optical (light) signal. In one embodiment, emitter 112 is integrated with the logic control circuits of power module 100 at room temperature.

Additionally, as shown in FIG. 1D, optical fiber-based isolator 105 includes optical fiber cable 106 in optical communication with emitter 105 and detector 107. As previously discussed, in one embodiment, optical fiber cable 106 is configured to transfer an optical (light) signal from emitter 112 to detector 107.

Furthermore, as shown in FIG. 1D, optical fiber-based isolator 105 includes detector 107, which is configured to convert the optical signal (light signal) received from optical fiber cable 106 to an electrical signal.

The power modules of the present disclosure can be in various forms. For instance, in some embodiments, power module 100 is a silicon carbide (SiC)-based power module. In some embodiments, power module 100 is a high density power module. In some embodiments, power module 100 is operable at temperatures of 200° C. and higher.

In one embodiment, high-temperature gate drivers 103 with optical fibers as galvanic isolators (see optical fiber-based isolator 105) are integrated into SiC power module 100 to increase the power density. In one embodiment, gate driver 103 is fabricated based on LTCC substrates 111 to ensure reliable thermal performance.

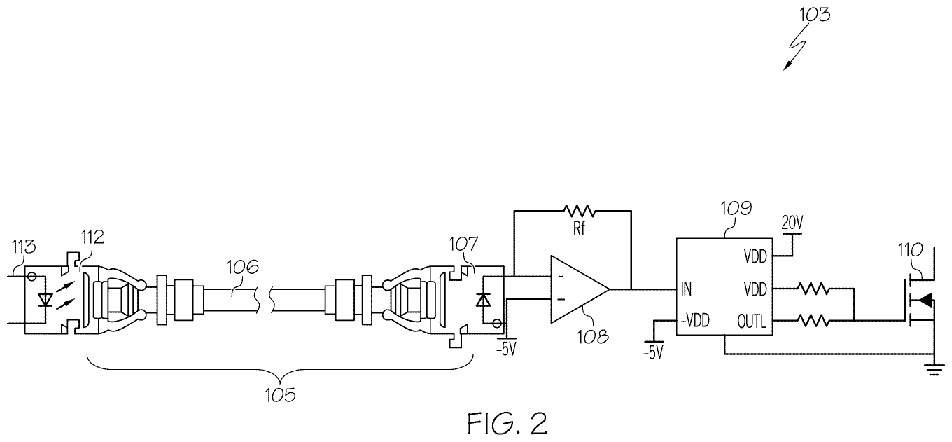

Referring now to FIG. 2, FIG. 2 illustrates the schematic of a high-temperature SiC power module 100 with an integrated gate driver 103 in accordance with an embodiment of the present disclosure.

As shown in FIG. 2, in one embodiment, a high-temperature optical fiber cable 106 of optical fiber-based isolator 105 is used to transfer an optical (light) signal from emitter 112 to detector 107. In one embodiment, emitter 112 converts a received electrical signal 113 into a corresponding optical (light) signal, which is transferred to detector 107 via optical fiber cable 106. In one embodiment, detector 107 converts the optical signal (light signal) received from optical fiber cable 106 to an electrical signal.

In one embodiment, optical fiber-based isolator 105 is configured to protect the low-voltage devices from the high-voltage switches (power devices) 110. In one embodiment, a high-power laser diode is utilized as emitter 112 of optical fiber-based isolator 105, and a high-temperature detector is used as detector 107.

Furthermore, as illustrated in FIG. 2, in one embodiment, amplifier 108 is a transimpedance amplifier (TIA) designed by using a high-temperature operational amplifier, which converts the photocurrent from detector 107 to a voltage signal for gate driver integrated circuit 109. In one embodiment, gate driver integrated circuit 109 is utilized to provide sufficient voltage and current to drive power devices 110.

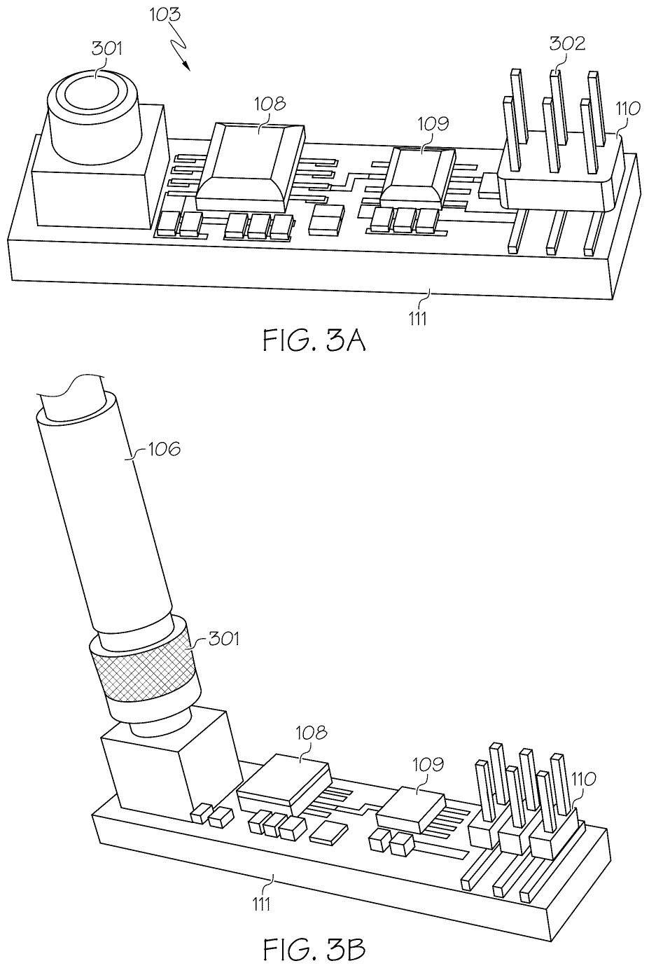

Referring now to FIG. 3A, FIG. 3A illustrates a three-dimensional model of gate driver 103 in accordance with an embodiment of the present disclosure.

As shown in FIG. 3A, in one embodiment, gate driver 103 is fabricated on LTCC substrate 111, and a 3D-printed optical fiber interface 301 is used for the connection of optical fiber cable 106 with detector 107.

In one embodiment, the output pads of the LTCC-based gate driver 103 are on the bottom layer, which allows gate driver 103 to connect with power devices 110 by copper traces (on direct bond copper (DBC)) and bond wires. This not only increases the power density of the system but also reduces the parasitic gate loop inductance and increases the switching speed. In one embodiment, LTCC-based gate driver 103 with optical fiber cable 106 as a galvanic isolator has been fabricated. That is, LTCC-based gate driver 103 achieves galvanic isolation (no physical or electrical connection between two circuits thereby preventing unwanted current flow and protecting against high voltages) by utilizing optical fiber cable 106, which transmits pulses of light through glass or plastic strands, which are then converted back into electrical signals by detector 107 thereby effectively decoupling the two circuits electrically.

Furthermore, FIG. 3A illustrates the signal and power pins 302 of power devices 110.

An example of such a fabricated sample of LTCC-based gate driver 103 is shown in FIG. 3B in accordance with an embodiment of the present disclosure.

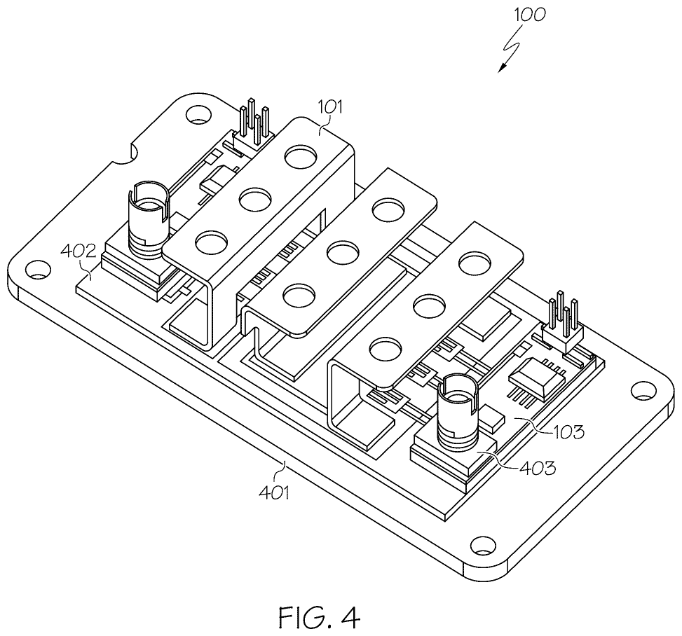

Referring now to FIG. 4, FIG. 4 illustrates high-temperature SiC power module 100 with LTCC-based optical fiber-based isolated gate drivers 103 in accordance with an embodiment of the present disclosure.

In one embodiment, the length, width, and height of power module 100 are 105 mm, 50 mm, and 20 mm, respectively. In one embodiment, optical fiber-based isolator 105 is integrated into LTCC-based gate driver 103 to reduce the propagation delay and increase the switching frequency of the high-temperature power module.

As shown in FIG. 4, two LTCC-based high-temperature gate drivers 103 are integrated into power module 100 to achieve low parasitic inductance and reduce the system size and weight. In one embodiment, power devices 110 are packaged in power module 100. In one embodiment, high-temperature materials and components are used to achieve an operating temperature of 200° C.

Furthermore, as shown in FIG. 4, power module 100 includes a baseplate 401, which serves as a component for heat dissipation and electrical connection. In one embodiment, baseplate 401 acts as a thermal interface for transferring heat generated by power devices 110 (e.g., IGBTs, MOSFETs) to a heat sink thereby preventing overheating and ensuring reliable operation.

Additionally, as shown in FIG. 4, gate driver 103 is connected with power devices 110 by copper traces on direct bond copper (DBC) substrate 402.

Furthermore, as shown in FIG. 4, detector 107 includes a photodetector 403, which is configured to convert incident light or optical power into a measurable electrical signal.

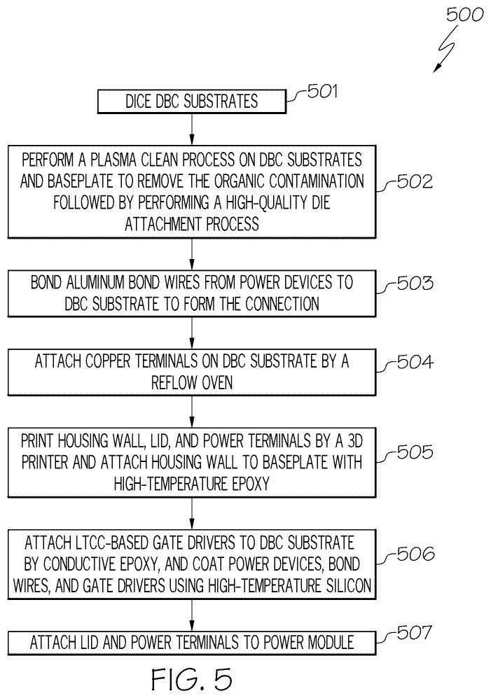

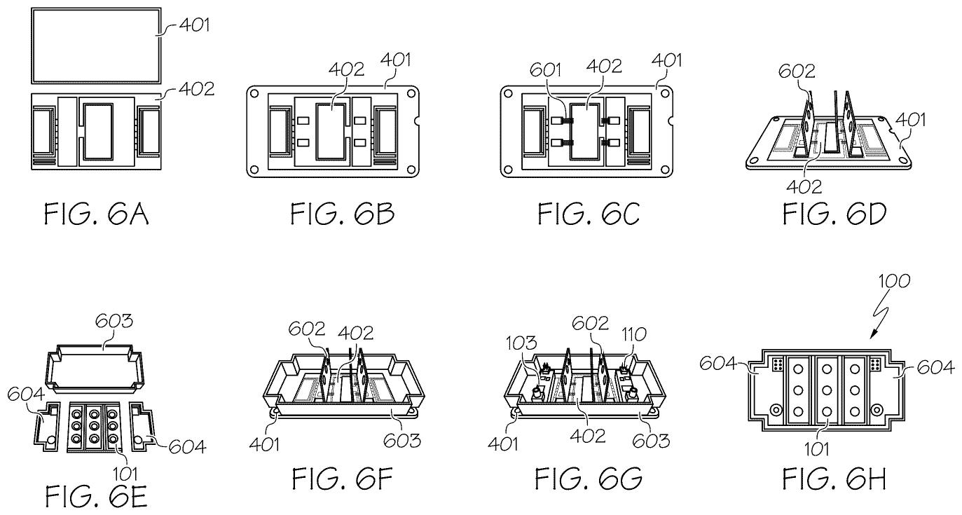

Referring now to FIGS. 5 and 6A-6H, FIG. 5 is a flowchart of a method 500 for fabricating high-temperature SiC power module 100 of FIG. 4 in accordance with an embodiment of the present disclosure. FIGS. 6A-6H depict the cross-sectional views for fabricating high-temperature SiC power module 100 of FIG. 4 using the steps described in FIG. 5 in accordance with an embodiment of the present invention.

Referring to FIG. 5, in conjunction with FIGS. 4 and 6A-6H, in step 501, DBC substrates 402 are diced by a dicing saw to form the desired sizes as shown in FIG. 6A.

In step 502, a plasma clean process is performed on DBC substrates 402 and baseplate 401 to remove the organic contamination followed by performing a high-quality die attachment process as shown in FIG. 6B. In one embodiment, the die attachment process is carried out by silver sintering. For example, in one embodiment, high-temperature silver (Ag) paste is utilized to adhere power devices 110, DBC substrate 402, and baseplate 401. In one embodiment, the silver sintering process is conducted in a nitrogen oven.

In step 503, aluminum bond wires 601 are bonded from power devices 110 to DBC substrate 402 to form the connection as shown in FIG. 6C.

In step 504, copper terminals 602 are attached on DBC substrate 402 by a reflow oven as shown in FIG. 6D.

In step 505, after the terminal attachment, housing wall 603, lid 604, and power terminals 101 are printed by a 3D printer and housing wall 603 is attached to baseplate 401 with high-temperature epoxy as shown in FIGS. 6E-6F.

In step 506, LTCC-based gate drivers 103 are attached to DBC substrate 402 by conductive epoxy, and high-temperature silicone is used to coat power devices 110, bond wires, and gate drivers 103 (i.e., encapsulation process) as shown in FIG. 6G. In one embodiment, the encapsulation process is carried out at room temperature for 24 hours to remove the air bubbles trapped in the silicone, then performed at 150° C. for 1.5 hours to cure the silicone.

In step 507, lid 604 and power terminals 101 are attached to power module 100, and power terminals 101 are bent as shown in FIG. 6H.

The fabricated sample of high-temperature SiC power module 100 using method 500 is shown in FIG. 1A.

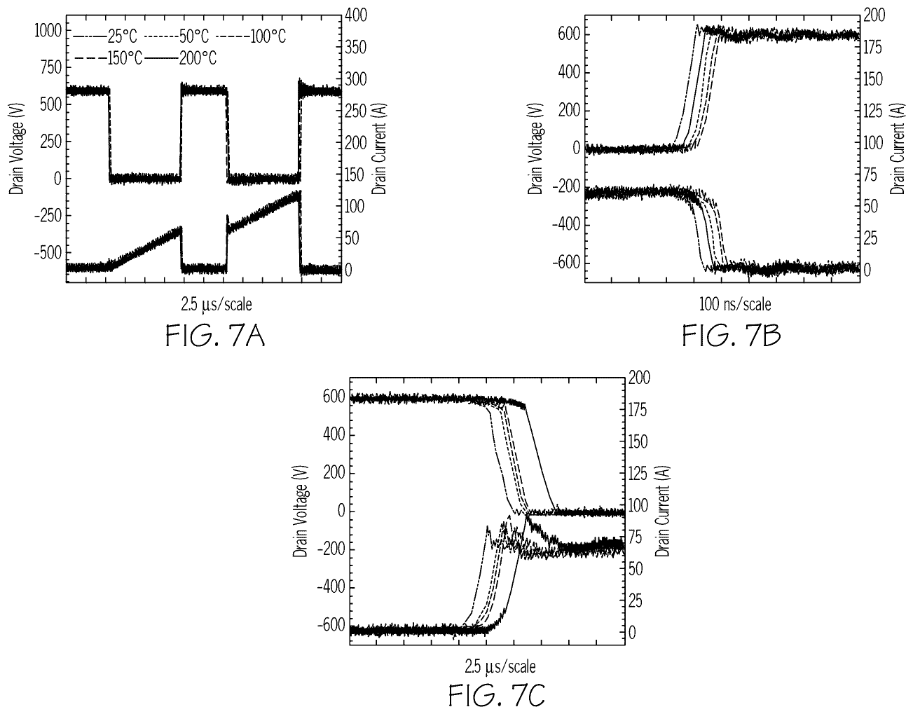

In one embodiment, double pulse tests (DPTs) were carried out on the high-temperature SiC power module 100 from 25° C. to 200° C. to characterize its switching performance. FIGS. 7A-7C illustrate the results from performing the double pulse tests (DPTs) on power module 100 from 25° C. to 200° C. in accordance with an embodiment of the present disclosure.

As illustrated in FIG. 7A, power module 100 was tested at a drain voltage of 600 V with a maximum current of 120 A and showed reliable switching performance from 25° C. to 200° C.

As shown in FIGS. 7B and 7C, the turn-on time and turn-off time of SiC power module 100 are from 55 ns to 75 ns and show little degradation with the temperature varying from 25° C. to 200° C.

SiC power electronic modules are of immense interest in many industrial applications, such as electric vehicles, space transportation, power grid, and industrial motor drive due to the high temperature tolerance, high blocking voltage, and high switching frequency of the SiC power devices. Optical fiber is immune to electromagnetic interface (EMI), which makes it a promising isolator for power systems. Plus, optical fibers can handle much higher frequencies over longer distances and achieve a high isolation voltage, which is good for fast-switching and high-density power modules. As a result of integrating an LTCC-based gate driver with an optical fiber-based isolator into SiC power modules as discussed herein, the SiC power module of the present disclosure not only achieves high density and high operating temperature but also improves the switching frequency, EMI, and isolation voltage for the SiC power module.

Advantages of the SiC power module of the present disclosure include higher operating temperatures and fast switching capability compared with conventional optocouplers, and an increase in the power density due to the decrease in size of the power module.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A power module, the power module comprising:
a gate driver, wherein said gate driver comprises:
one or more optical fiber-based isolators configured to provide electrical isolation between low-voltage circuitry and power devices of said power module;
an amplifier configured to enhance a control signal; and
a gate driver integrated circuit configured to provide voltage and current to drive said power devices of said power module based on said control signal.

2. The power module as recited in claim 1, wherein said gate driver is fabricated on a substrate.

3. The power module as recited in claim 2, wherein said substrate is a low-temperature co-fired ceramic substrate.

4. The power module as recited in claim 1, wherein each of said one or more optical fiber-based isolators comprises:
an emitter configured to convert a first electrical signal into a corresponding optical signal; and
a detector configured to convert said optical signal into a second electrical signal.

5. The power module as recited in claim 4, wherein said second electrical signal corresponds to said control signal which is enhanced by said amplifier.

6. The power module as recited in claim 4, wherein each of said one or more optical fiber-based isolators further comprises:
an optical fiber cable configured to transfer said optical signal from said emitter to said detector.

7. The power module as recited in claim 6, wherein said gate driver comprises a 3D-printed optical fiber interface used for a connection of said optical fiber cable with said detector.

8. The power module as recited in claim 4, wherein said emitter is integrated with logic control circuits of said power module that operate at room temperature.

9. The power module as recited in claim 4, wherein said detector is a photodetector for converting said optical signal to said second electrical signal.

10. The power module as recited in claim 4, wherein said amplifier is a transimpedance amplifier configured to convert a photocurrent from said detector to a voltage signal for said gate driver integrated circuit.

11. The power module as recited in claim 1, wherein each of said one or more optical fiber-based isolators is immune from electromagnetic interference.

12. The power module as recited in claim 1, wherein said power module comprises two optical fiber-based isolators.

13. The power module as recited in claim 1 further comprising:
one or more power terminals for providing power supply connection to circuit boards of said power module.

14. The power module as recited in claim 1, wherein said power module is a silicon carbide (SiC)-based power module.

15. The power module as recited in claim 1, wherein said power module is operable at a temperature of 200° C.

16. The power module as recited in claim 1 further comprising:
a baseplate, which serves as a component for heat dissipation and electrical connection.

17. The power module as recited in claim 16, wherein said baseplate acts as a thermal interface for transferring heat generated by said power devices to a heat sink.

18. The power module as recited in claim 1, wherein said gate driver is connected with said power devices of said power module by copper traces on a direct bond copper substrate.

19. The power module as recited in claim 1, wherein said power devices comprise insulated gate bipolar transistors.

20. The power module as recited in claim 1, wherein said power device comprise metal oxide semiconductor field-effect transistors.
